(19) United States
(12) Patent Application Publication
(10) Pub. No.: US 2015/0173233 A1
(43) Pub. Date: Jun. 18, 2015

(54) Display Modules

(71) Applicant: AU Optronics Corporation, Hsin-Chu (TW)

(72) Inventors: AnHsu Lu, Hsin-Chu (TW); Cheng-Yu Wang, Hsin-Chu (TW); Cheng-Hao Kao, Hsin-Chu (TW)

(21) Appl. No.: 14/564,443

(22) Filed: Dec. 9, 2014

(30) Foreign Application Priority Data
Dec. 12, 2013 (TW) 102145889

(51) Int. Cl. H05K 7/14

(52) U.S. Cl. CPC H05K 7/14

(57) ABSTRACT

A display module is provided, which includes a display panel, an adhesive layer and a frame. The display panel includes a substrate and circuit elements. The substrate includes a first surface, a second surface and a side. The first surface and the second surface are contrary to each other. The circuit elements are disposed on the substrate where is close to the side of the first surface. The frame supports the display panel. The frame has a supporting part to support the substrate close to the side. The supporting part has a plurality of openings. The adhesive layer, disposed between the second surface of the substrate and the supporting part, is used to adhere the substrate to the supporting part.

### BACKGROUND OF THE INVENTION

1. Field of the Invention

The present invention relates to a display module. Generally speaking, it relates to a display module having a frame with openings.

2. Description of the Prior Art

In recent years, due to the rapid development of electronic information industry, its related products are also increasingly sophisticated. Such as liquid crystal display device with a high-quality, small size, light weight, low power consumption, etc., it is widely used in mobile devices. Mobile devices mentioned in the foregoing, in particular handheld device-related products, continue to go high-resolution, high-quality, large viewing angle of the direction of development, but need to reach handheld convenience slim and light, so people for the display module the thickness requirements have increasingly thin trend, thus indicating the major components within the module (for example: a display panel backlight module, etc.) must also do more thinner. However, due to the limited size of the space, the driver integrated circuit (Driver IC) lamination process in module works must rely glass flip chip package (Chip-On-Glass, COG) production.

In COG process of the display device, since the glass substrate and the driver integrated circuit (Driver IC) have different coefficients of expansion and contraction, the warp of the glass substrate is often occurred after a glass flip chip package caused by the contraction of driver integrated circuits, as shown in FIG. 1, the light leakage caused by the warp of the substrate 21 and the circuit element 22, resulting in an uneven luminance blocks displayed on the display device.

### SUMMARY OF THE INVENTION

In view of the above problems, the present invention provides a display module, especially a display module having a frame with openings.

In one aspect, the present invention provides a display module to mitigate the warp of glass substrates.

In another aspect, the present invention provides a display module to reduce the light leakage of the edge of the active area(AA) or the non-uniform of the light distribution.

In one embodiment, the present invention provides a display module, such as a normally black type display panel. The display panel comprises a substrate and a circuit element. The substrate has a first surface, a second surface which is contrary to the first surface, and a side between the first surface and the second surface. The circuit element is disposed on the first surface close to the side of the substrate. A frame is configured to support the display panel, wherein the frame has a supporting part for supporting the substrate at a position close to the side. On the supporting part is an opening. At least a portion of the orthogonal projection of the circuit element projected on the supporting part overlapped with the opening. An adhesive layer is disposed between the second surface of the substrate and the supporting part configured to adhere the substrate to part of the supporting part.

In one embodiment, the present invention provides a display module, such as a normally white type display panel. The display panel comprises a substrate and a circuit element. The substrate has a first surface, a second surface which is contrary to the first surface, and a side between the first surface and the second surface. The circuit element is disposed on the first surface close to the side of the substrate. A frame configured to support the display panel, wherein the frame has a supporting part for supporting at a position close to the side. On the supporting part is an opening. The orthogonal projection of the circuit element projected on the supporting part does not overlap with the opening.

The following description and the drawings set forth certain illustrative advantages and spirits of the specification.

### BRIEF DESCRIPTION OF THE DRAWINGS

FIG. 1 is a schematic diagram of warping phenomenon of a conventional substrate.

FIG. 2A is an exploded view diagram of a display module in an embodiment.

FIG. 2B is an exploded view diagram of a display module in an embodiment.

FIG. 2C is an exploded view diagram of a display module in an embodiment.

FIG. 2D is a schematic diagram of stress alteration between a substrate and a frame in an embodiment.

FIG. 2E is a schematic diagram of stress alteration related to FIG. 2D.

FIG. 3 is a cross-sectional schematic diagram of a substrate and a frame in an embodiment.

FIG. 4 is a cross-sectional schematic diagram of a substrate and a frame in an embodiment.

FIG. 5 is a cross-sectional schematic diagram of a substrate and a frame in an embodiment.

FIG. 6 is a cross-sectional schematic diagram of a substrate and a frame in an embodiment.

FIG. 7A is a schematic diagram of stress alteration between a substrate and a frame in an embodiment.

FIG. 7B is a schematic diagram of stress alteration related to FIG. 7A.

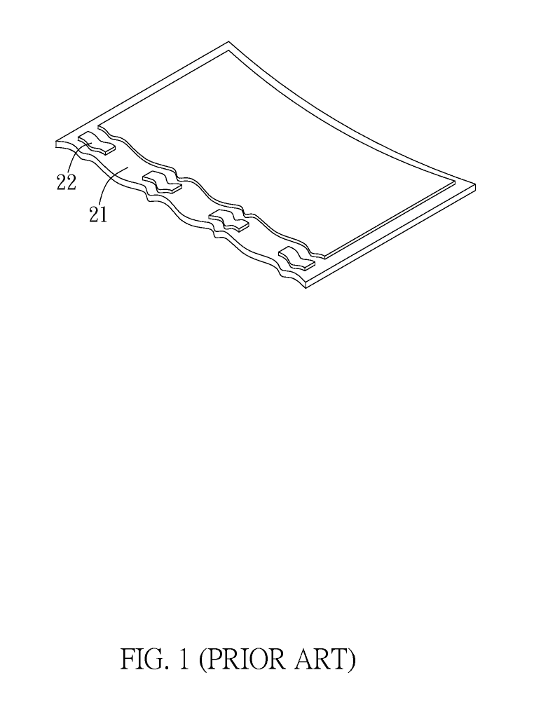

### DETAILED DESCRIPTION OF THE PREFERRED EMBODIMENT

The following will disclose a plurality of embodiment with texts and drawings.

For a clear illustration, many details in practice will be described in the following description. However, it should be understand that the details of the practical application of these are not to limit the present invention. In addition, for the sake of simplifying the drawings, some of the conventional structures and components in the drawings will be depicted in a simplified schematic manner.

The present invention relates to a display module having a frame with openings. The display module could be a liquid crystal display (LCD) module, an organic light emitting diode (OLED) display module, an electro-phoretic display (EPD) module, etc. Specifically, a supporting part of the frame has an opening corresponding to the circuit element of the substrate, and the substrate is adhered to the supporting part of the frame by an adhesive layer. Accordingly, it can uniform the level of the warp of the substrate and reduce the mura phenomenon caused by non-uniform brightness due to the contract stress. The display module used in this invention may be portable computer devices (such as laptops, tablet PCs, etc.) or handheld devices (such as mobile phones, game consoles, PDA, etc.), but not limited. In other words, as long as there are requirements for uniforming the warp of the substrate, they all can be introduced into the design of display modules in the present invention.

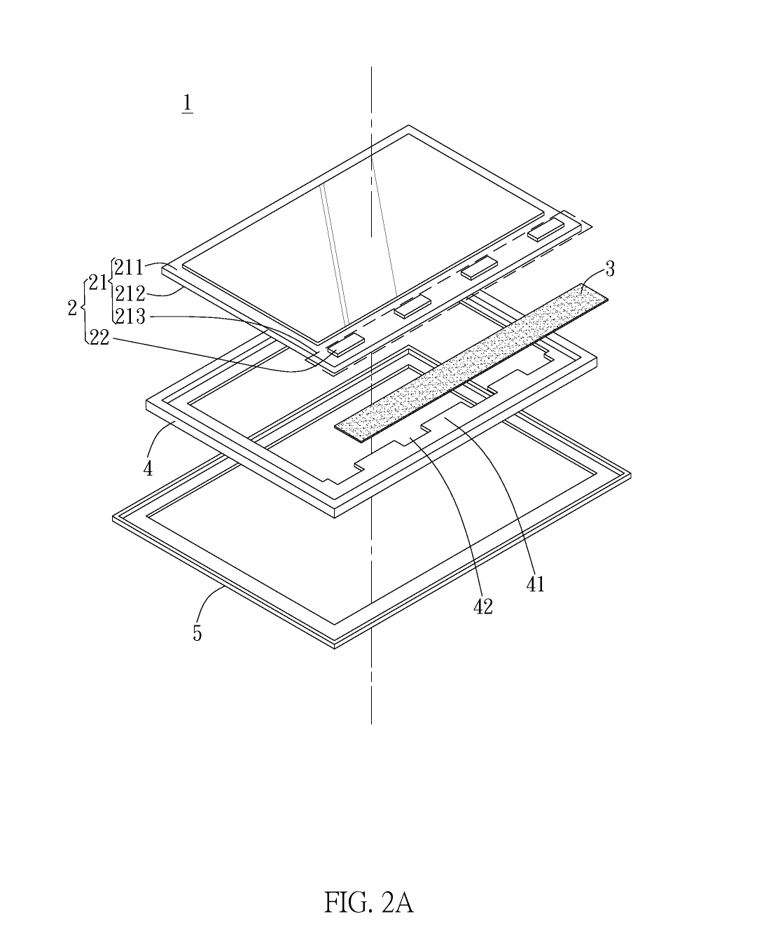

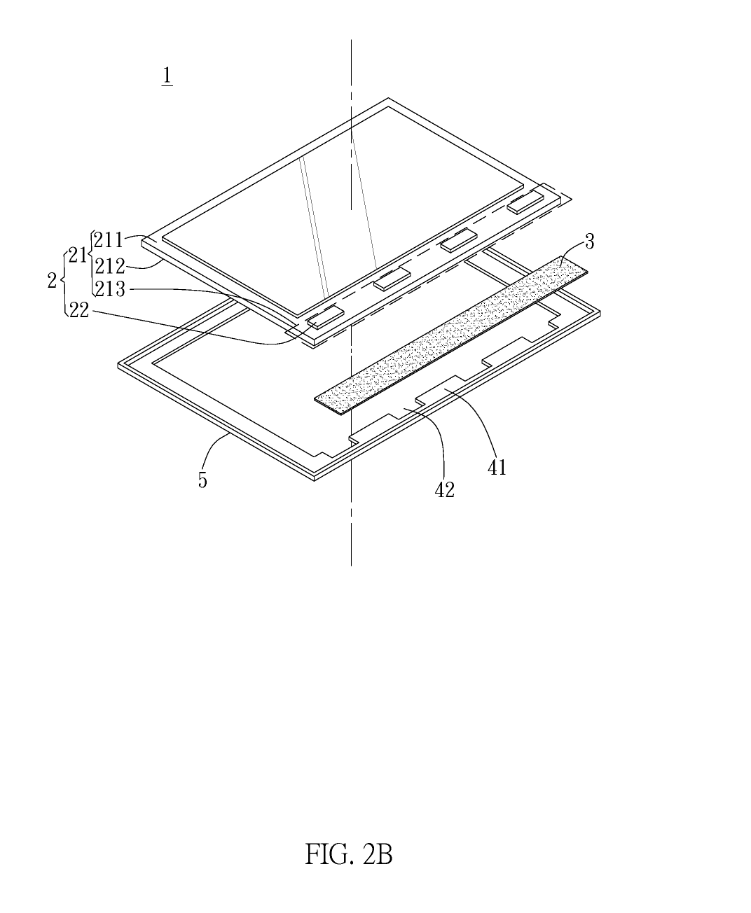

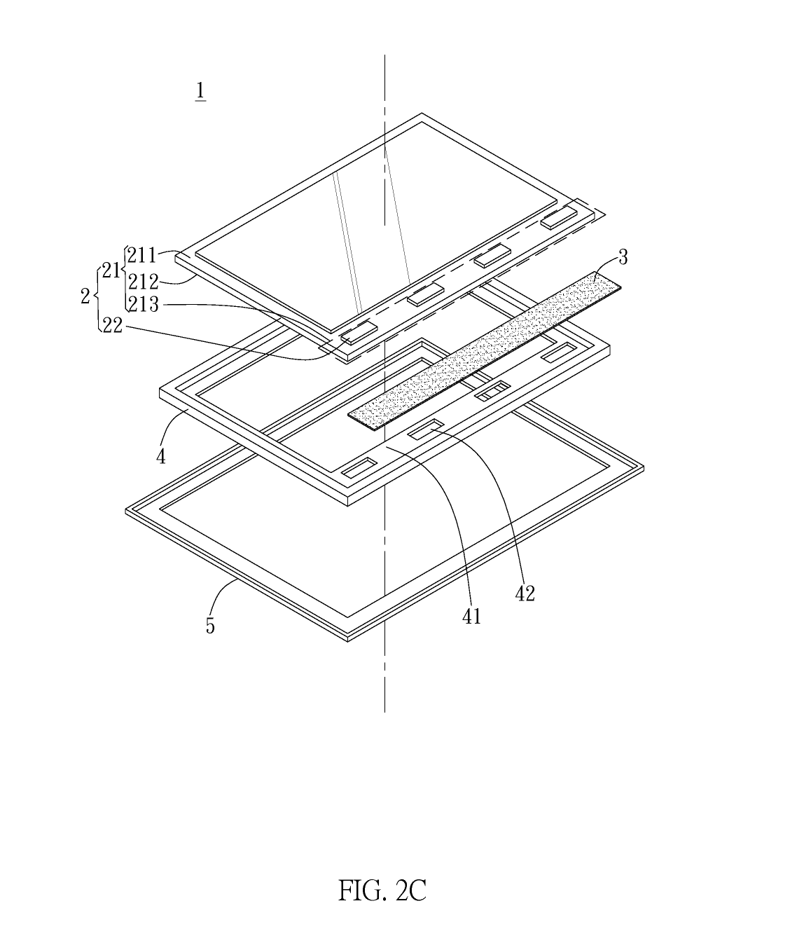

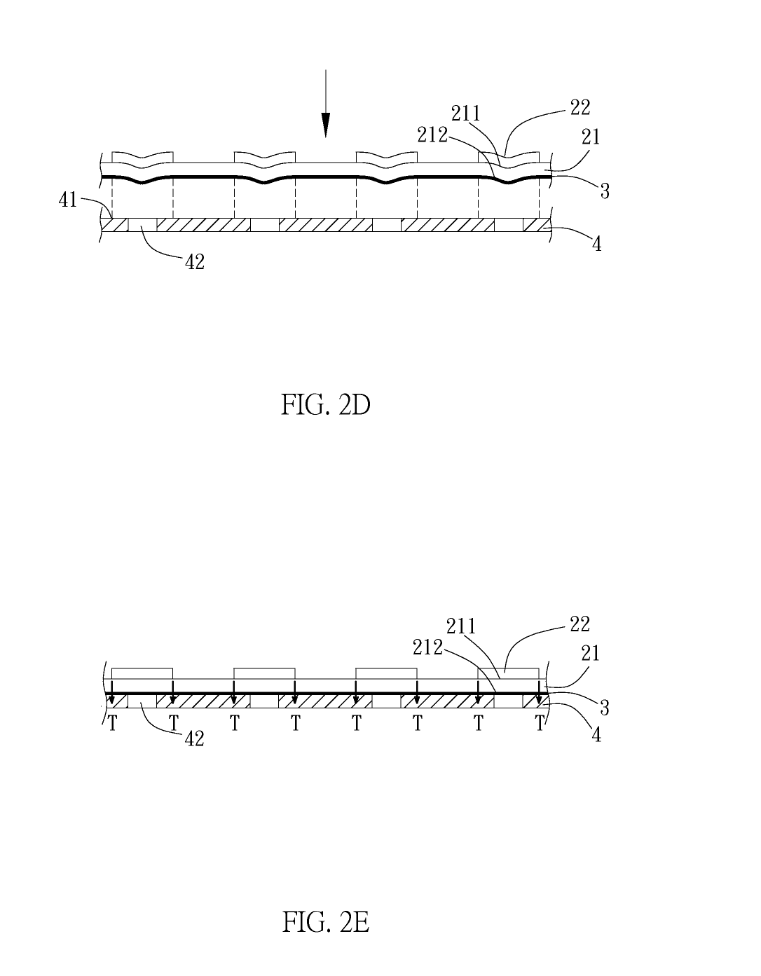

Please refer to FIG. 2A. FIG. 2A is an exploded view diagram of a display module in an embodiment. As shown in FIG. 2A, in this embodiment, a display module 1 comprises a display panel 2, a frame 4, an adhesive layer 3, and a rear bezel 5. The display panel 2 comprises a substrate 21 and a plurality of circuit elements 22 thereon. The substrate 21 has a first surface 211, a second surface 212 which is contrary to the first surface 211, and a side 213 between the first surface 211 and the second surface 212. The circuit elements 22 are disposed on the first surface 211 close to the side 213 of the substrate 21 by heat bonding. In addition to the material of glass, the material of the substrate 21 may be plastic material adopted for the flexible panel.

As shown in FIG. 2A, the frame 4 is configured to support the display panel 2, wherein the frame 4 has a supporting part 41 to support the substrate 21 close to the side 213, and there are a plurality of openings 42 on the supporting part 41. An edge of each of the openings 42 is opened. The advantage of this configuration is easy to manufacture. The adhesive layer 3 is disposed between the second surface 212 of the substrate 21 and the supporting part 41, which is configured to adhere the substrate 21 to the supporting part. In this embodiment, the frame 4 is a plastic frame in the backlight module, to support the display panel 2 and locate the display panel 2 above the light source (not shown). The material of the frame 4 may be plastic or other materials with appropriate structural strength.

Please refer to FIG. 2B. FIG. 2B is an exploded view diagram of a display module in an embodiment. In this embodiment, the backlight module does not include a plastic frame, while the rear bezel 5 in the backlight module also serve as the frame and is configured to support the display panel 2 and locate the display panel 2 above the light source (not shown). The material of the rear bezel 5 may be metal or other materials with appropriate structural strength. Because the strength of the rear bezel 5 in this embodiment is stronger than the plastic frame, the thickness could be thinner.

In the above embodiment, the display panel 2 is preferable a normally black type display panel. When there is no voltage applied, the arrangement of the liquid crystal and the setting of the polarizer are configured to block the light to pass through, it displays a dark image. When a voltage is applied, the liquid crystal is driven to twist arrangement to allow the light passing, it displays a bright image. Therefore, when the normally black type display panel has tension due to contraction of the circuit element results in non-uniform of brightness, it sometimes produces the whitish phenomenon at both ends of the circuit element. So in those embodiments, making the adhesive layer and the stronger portions of the frame or the rear bezel correspond to the both ends of the circuit element. Using the under tension to correct the level of the warp so that the average brightness of the original whitish of light leakage area could be reduced.

According to one embodiment in the present invention, as shown in FIG. 2C, the frame 4 of the display module 1 has a supporting part 41 to support the substrate 21 close to the side 213, and there are a plurality of openings 42 on the supporting part 41. In this embodiment, the openings 42 can be through holes or blind holes, this configuration has the advantage of stronger structure in mechanics. The openings 42 could be a rectangle, but not limited.

As shown in FIG. 2D and FIG. 2E, at least part of the orthogonal projection of the circuit element 22 projected on the supporting part 41 is overlapped with the openings 42. Because of the warp, there is a first contract stress on the first surface 211 of the substrate 21 which contacts with the circuit element 22, there is a second contract stress on the second surface 212 of the substrate 21 which is below the circuit element 22, and the first contract stress is stronger than the second contract stress. At this time, the adhesive layer 3 is utilized to adhere the substrate 21 to the frame 21 or the rear bezel 5, the downward tensions T are generated between the adhesive layer 3 and the frame 4 at both ends of the circuit element 22 to correct the level of warp due to the stress for reducing the average brightness of the original whitish of light leakage area.

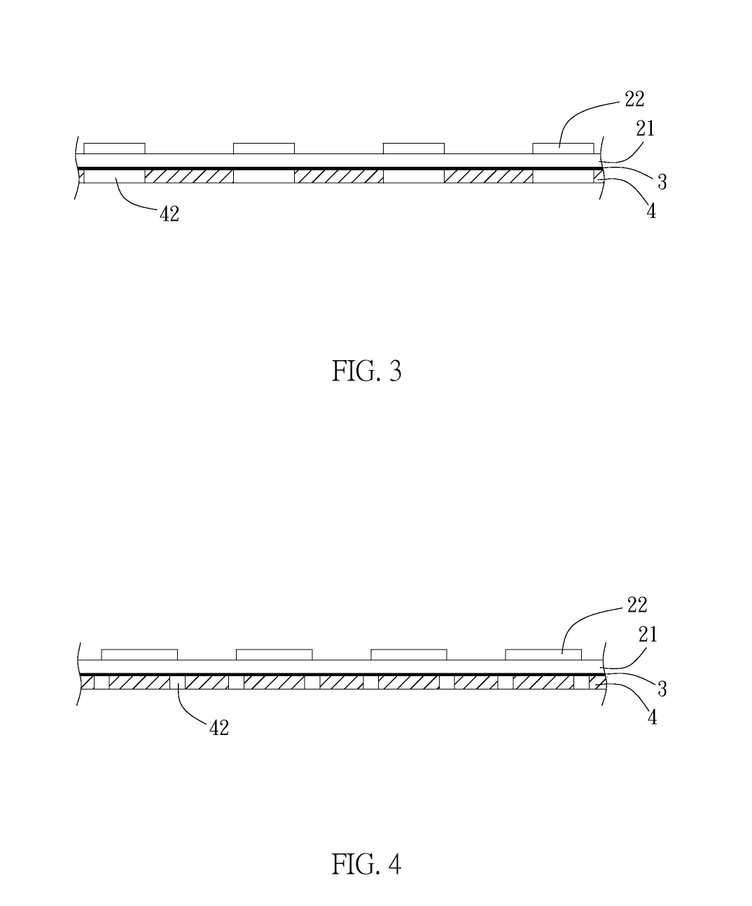

According to an another embodiment in the present invention, such as the circuit elements used in general notebook computers, because of the bigger size of the panel than that of the handheld device, they need more circuit elements. Therefore the length of the circuit elements is shorter, e.g. usually less than 25 mm. Each circuit element 22 preferable corresponds to a single opening 42. As shown in FIG. 3, the orthogonal projection of the circuit element 22 projected on the supporting part 41 completely falls into the length range of the openings 42. However, the orthogonal projection of the circuit element 22 projected on the supporting part 41 is not limited to align with the length range of the openings 42. It could be based on the situation of the warp of the substrate 21 to decide the ratio between the circuit element 22 and the openings 42.

According to a yet another embodiment in the present invention, such as the circuit elements used in cell phones. Compared to the panels of the notebook computers, because of the smaller panel size, the number of circuit elements in cell phones are less, and the length of them is longer, e.g. usually greater than 30 mm. However, in this situation, because the position of mura generated by non-uniform brightness caused by the tension easily overlaps with the range of the circuit element, thus we can set two or more openings 42 under each circuit element 42 to eliminate the situation of warp of the substrate 21. As shown in FIG. 4, the circuit element 22 traverses above two adjacent openings 42 parallel to an extending direction of the side 213, and the orthogonal projection of the circuit element 22 projected on the supporting part 41 overlaps with part of the two adjacent openings 42 respectively. In this configuration, the light leakage of both ends of the circuit element 22 could be eliminated by setting the openings 42 on the supporting part 41 of the frame 4. In the meantime, the rigid structure of frame 4 or rear bezel 5 between two adjacent openings under the circuit element 22 still exist to provide the strength of supporting the substrate 21.

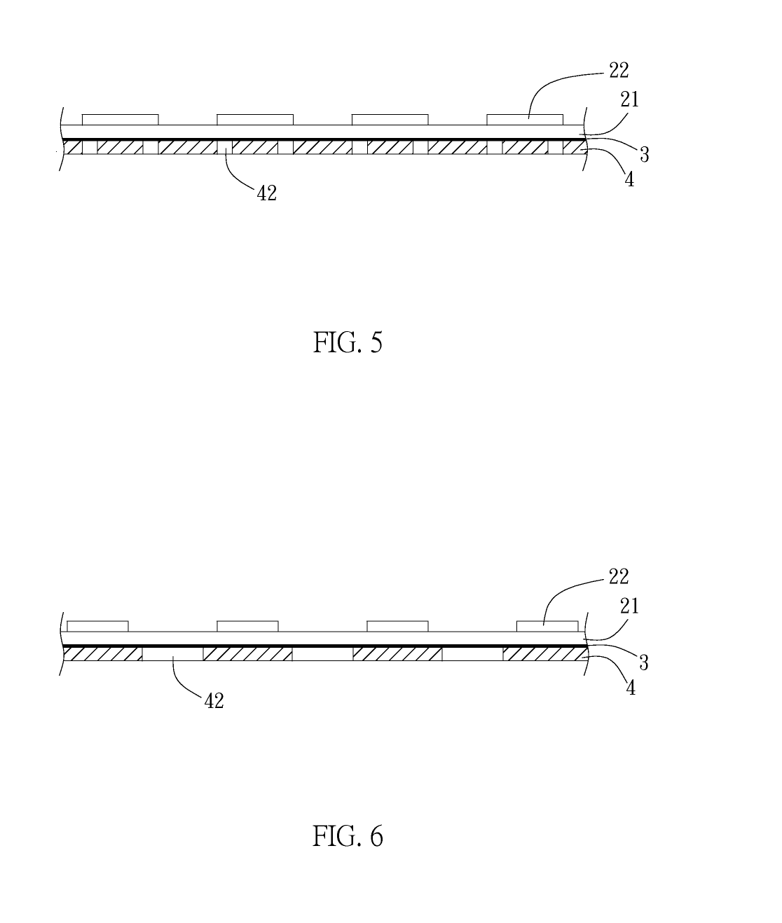

According to yet another embodiment in the present invention, please refer to FIG. 5. the circuit element 22 traverses above two adjacent openings 42 parallel to the extending direction of the side 213, and the orthogonal projection of the circuit element 22 projected on the supporting part 41 totally covers both the two adjacent openings 42. By adjusting the relationship of the projection position between the openings 42 and the edge of the circuit element 22 can adjust and control different light leakage situations.

According to an embodiment in the present invention, the display panel 2 is preferable a normally white type display panel. Such the display panel, when there is no voltage applied, the arrangement of the liquid crystal and the setting of the polarizer are configured to allow the light pass, it displays a bright image. When applying a voltage, liquid crystal is driven to twist arrangement to block the light to pass through, it displays a dark image. Therefore, when the normally white type display panel produces tension due to contraction of the circuit element results in non-uniform of brightness, it sometimes produces the blackish phenomenon at both ends of the circuit element. So in the following embodiments, making the adhesive layer and the stronger portions of the frame or the rear bezel correspond to the position under the circuit element to increase the stress to make the warp much more obvious. Let the image of the side 213 of the display panel become uniform darkness.

Such as the circuit elements used in general notebook computers, because of the bigger size of the panel than that of the handheld device, they need more circuit elements. Therefore the length of the circuit elements is shorter, e.g. usually less than 25 mm. Each circuit element 22 preferably corresponds to the supporting part 41 without corresponding to the openings. As shown in FIG. 6, the orthogonal projection of the circuit element 22 projected on the supporting part 41 does not overlap with the openings 42. However, the length range of the openings 42 could be based on the situation of the warp of the substrate 21 to decide the length ratio between the circuit element 22 and the openings 42.

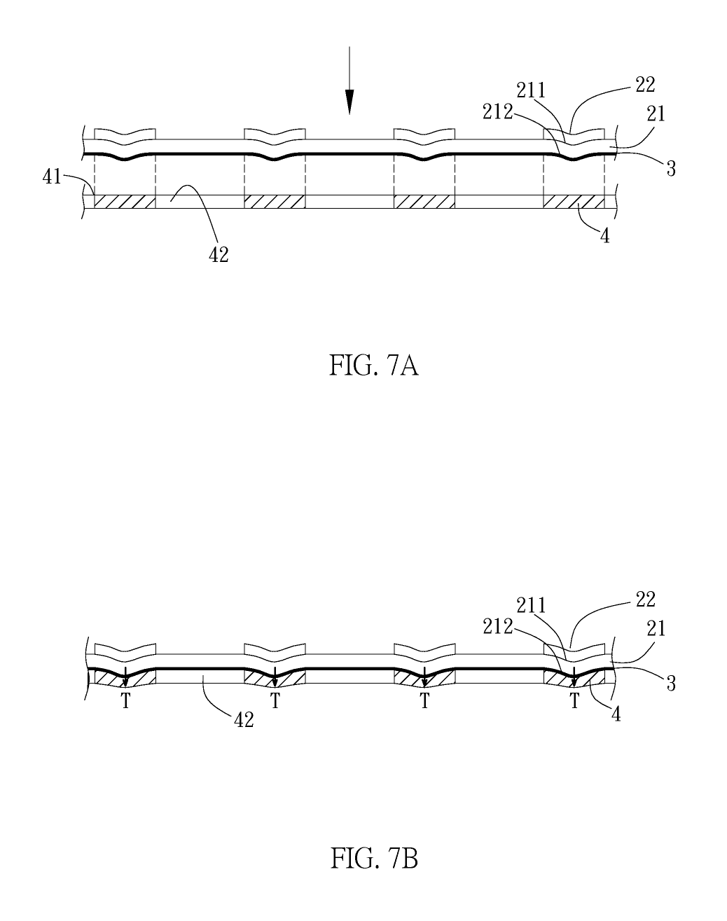

As shown in FIG. 7A and FIG. 7B, the orthogonal projection of the circuit element 22 projected on the supporting part 41 is adjacent to the openings 42 while not overlapping. Because of the warp, there is a first contract stress on the first surface 211 of the substrate 21 which contacts with the circuit element 22, there is a second contract stress on the second surface 212 of the substrate 21 which is below the circuit element 22, and the first contract stress is stronger than the second contract stress. At this time, the adhesive layer 3 is utilized to adhere the substrate 21 to the frame 21 or the rear bezel 5, the downward tension T of the adhesive layer 3 disposed under the circuit element 22 to increase the warp. Let the image of the side 213 of the display panel become uniform darkness.

It is noted that the rest embodiments are based on the openings shown in FIG. 2C to do the same variation as above-mentioned embodiments, it does not repeat here.

Compared with the prior art, the display module has a frame with openings in the present invention, using the partial openings on the supporting part of the frame and the positions corresponding to the circuit elements on the substrate, to make the warp level of the substrate uniform for improving the light leakage of different display panels.

Although the preferred embodiments of the present invention have been described herein, the above description is merely illustrative. Further modification of the invention herein disclosed will occur to those skilled in the respective arts and all such modifications are deemed to be within the scope of the invention as defined by the appended claims.

What is claimed is:

1. A display module, comprising:
a display panel, comprising:
a substrate comprises a first surface, a second surface which is contrary to the first surface, and a side between the first surface and the second surface; and
at least one circuit element disposed on the first surface close to the side of the substrate;
a frame configured to support the display panel, wherein the frame has a supporting part for supporting the substrate at a position close to the side, the supporting part has at least one opening, at least a portion of the orthogonal projection of the circuit element projected on the supporting part overlapped with the opening; and
an adhesive layer disposed between the second surface of the substrate and the supporting part configured to adhere the substrate to the supporting part.

2. The display module of claim 1, wherein the orthogonal projection of the circuit element projected on the supporting part is substantially within a length range of the opening.

3. The display module of claim 2, wherein the length of the circuit element is less than 25 mm.

4. The display module of claim 1, wherein the orthogonal projection of the circuit element projected on the supporting part overlaps with a part of the opening.

5. The display module of claim 1, wherein the circuit element overlaps with two adjacent openings, and the orthogonal projection of the circuit element projected on the supporting part overlaps with a part of each of the two adjacent openings respectively.

6. The display module of claim 5, wherein a length of the circuit element is greater than 30 mm.

7. The display module of claim 1, wherein the circuit element overlaps with two adjacent openings, and the orthogonal projection of the circuit element projected on the supporting part totally covers both the two adjacent openings.

8. The display module of claim 1, wherein the display panel is a normally black type panel.

9. A display module, comprising:
a display panel, comprising:
a substrate comprises a first surface, a second surface which is contrary to the first surface, and a side between the first surface and the second surface; and
at least one circuit element disposed on the first surface close to the side of the substrate;
a frame configured to support the display panel, wherein the frame has a supporting part for supporting the substrate at a position close to the side, the supporting part has at least one opening, the orthogonal projection of the circuit element projected on the supporting part does not overlap with the opening; and
an adhesive layer disposed between the second surface of the substrate and the supporting part configured to adhere the substrate to the supporting part.

10. The display module of claim 9, wherein the orthogonal projection of the circuit element projected on the supporting part is adjacent to the opening.

11. The display module of claim 9, wherein the display panel is a normally white type panel.
